(19) United States
(12) Patent Application Publication
(10) Pub. No.: US 2023/0389393 A1
(43) Pub. Date: Nov. 30, 2023

(54) DISPLAY DEVICE

(71) Applicant: Japan Display Inc., Tokyo (JP)

(72) Inventors: Hiroumi KINJO, Tokyo (JP); Hayata AOKI, Tokyo (JP); Masumi NISHIMURA, Tokyo (JP)

(73) Assignee: Japan Display Inc., Tokyo (JP)

(21) Appl. No.: 18/448,989

(22) Filed: Aug. 14, 2023

Related U.S. Application Data
(63) Continuation of application No. PCT/JP2021/048239, filed on Dec. 24, 2021.

(30) Foreign Application Priority Data
Feb. 17, 2021 (JP) 2021-023572

(51) Int. Cl. H10K 59/80; H10K 59/122

(52) U.S. Cl. CPC H10K 59/80515; H10K 59/122

(57) ABSTRACT

According to one embodiment, a display device comprises a rib including an aperture and an upper surface, a partition on the upper surface, a first electrode overlapping the aperture, an organic layer including a first end portion on the upper surface and covering the first electrode, a second electrode including a second end portion on the upper surface and covering the organic layer, a first inorganic layer on the rib, and a second inorganic layer covering the partition, the second electrode, and the first inorganic layer. At least a part of the first inorganic layer is located between the first end portion and the partition and is in contact with the second inorganic layer.

### CROSS-REFERENCE TO RELATED APPLICATIONS

This application is a Continuation Application of PCT Application No. PCT/JP2021/048239, filed Dec. 24, 2021 and based upon and claiming the benefit of priority from Japanese Patent Application No. 2021-023572, filed Feb. 17, 2021, the entire contents of all of which are incorporated herein by reference.

### FIELD

Embodiments described herein relate generally to a display device.

### BACKGROUND

Recently, display devices having organic light emitting diodes (OLED) applied thereto as display elements have been put into practical use. This display element comprises a first electrode, a second electrode, and an organic layer arranged between these electrodes. The organic layer emits light in response to a voltage between the first electrode and the second electrode.

In general, the organic layer has a low resistance to moisture. If moisture reaches the organic layer for some reason, this can be a factor of causing degradation in display quality, such as a decrease in the luminance of a display element when emitting light.

### BRIEF DESCRIPTION OF THE DRAWINGS

FIG. 1 is a view showing a configuration example of a display device according to a first embodiment.

FIG. 2 is a view showing an example of a layout of sub-pixels according to the first embodiment.

FIG. 3 is a schematic cross-sectional view showing the display device along line III-III in FIG. 2.

FIG. 4 is a cross-sectional view showing an example of a layer configuration applicable to an organic layer according to the first embodiment.

FIG. 5 is a schematic plan view showing an example of a configuration that can be applied to a rib aperture, a first inorganic layer, and power supply lines, according to the first embodiment.

FIG. 6 is a schematic cross-sectional view showing the display device along line VI-VI in FIG. 5.

FIG. 7 is a schematic cross-sectional view showing the display device along line VII-VII in FIG. 5.

FIG. 8 is a schematic plan view showing a first inorganic layer and a power supply line according to a second embodiment.

FIG. 9 is a schematic cross-sectional view showing the display device along line IX-IX in FIG. 8.

FIG. 10 is a schematic cross-sectional view showing a display device according to a third embodiment.

FIG. 11 is a schematic cross-sectional view showing a display device according to a fourth embodiment.

FIG. 12 is a schematic cross-sectional view showing a display device according to a fifth embodiment.

FIG. 13 is a schematic cross-sectional view showing another example of the display device according to the fifth embodiment.

FIG. 14 is a schematic cross-sectional view showing a display device according to a sixth embodiment.

### DETAILED DESCRIPTION

In general, according to an embodiment, a display device comprises: a rib including an aperture and an upper surface; a partition arranged on the upper surface of the rib; a first electrode overlapping with the aperture; an organic layer including a first end portion located on the upper surface, and covering the first electrode; a second electrode including a second end portion located on the upper surface, and covering the organic layer; a first inorganic layer arranged on the rib; and a second inorganic layer covering the partition, the second electrode, and the first inorganic layer. At least a part of the first inorganic layer is located between the first end portion and the partition and is in contact with the second inorganic layer.

According to another embodiment, a display device comprises: a rib including an aperture and an upper surface; a partition arranged on an upper surface of the rib and including a first inorganic layer; a first electrode overlapping with the aperture; an organic layer including a first end portion located on the upper surface, and covering the first electrode; a second electrode including a second end portion located on the upper surface, and covering the organic layer; and a second inorganic layer covering the partition and the second electrode. The partition includes a first portion having a first width, and a second portion having a second width smaller than the first width. The second portion is located between the first portion and the rib and includes the first inorganic layer. At least a part of the first inorganic layer is in contact with the second inorganic layer.

According to this configuration, a display device capable of improving the display quality can be provided.

Several embodiments will be described hereinafter with reference to the accompanying drawings.

The disclosure is merely an example, and proper changes within the spirit of the invention, which are easily conceivable by a person of ordinary skill in the art, are included in the scope of the invention as a matter of course. In addition, in some cases, in order to make the description clearer, the widths, thicknesses, shapes and the like, of the respective parts are schematically illustrated in the drawings, compared to the actual modes. However, the schematic illustration is merely an example, and adds no restriction to the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis and a Z-axis orthogonal to each other are described to facilitate understanding as needed. A direction along the X-axis is referred to as a first direction, a direction along the Y-axis is referred to as a second direction, and a direction along the Z-axis is referred to as a third direction. A plane defined by the X-axis and the Y-axis is referred to as an X-Y plane, and a plane defined by the X-axis and Z-axis is referred to as an X-Z plane. Viewing the X-Y plane is referred to as plan view. A direction on an observer's side in the direction along the Z-axis is referred to as on or above, and a surface in the upper direction is referred to as an upper surface.

A display device DSP of the embodiments is an organic electroluminescent display device comprising an organic light emitting diode (OLED) as a display element, and can be mounted on televisions, personal computers, vehicle-mounted devices, tablet terminals, smartphones, mobile phones, and the like.

### First Embodiment

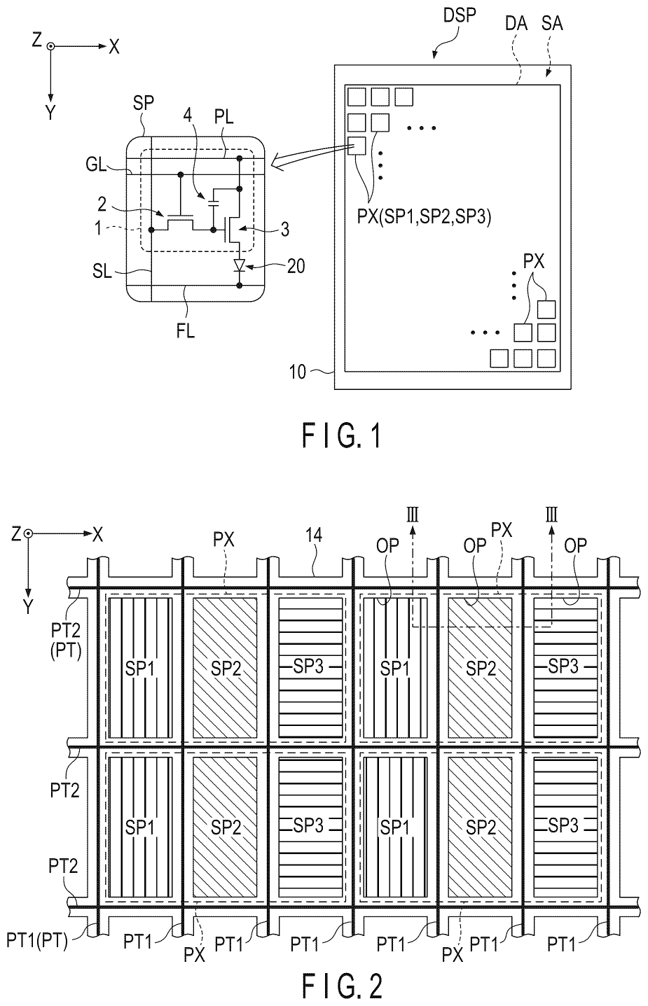

FIG. 1 is a view showing a configuration example of a display device DSP according to a first embodiment. The display device DSP has a display area DA where images are displayed and a surrounding area SA outside the display area DA, on an insulating substrate 10. The substrate 10 may be glass or a flexible resin film.

The display area DA includes a plurality of pixels PX arrayed in a matrix in the first direction X and the second direction Y. The pixel PX comprises a plurality of sub-pixels SP. As an example, the pixel PX comprises a red sub-pixel SP1, a green sub-pixel SP2, and a blue sub-pixel SP3. In addition to the sub-pixels of the above three colors, the pixel PX may comprise four or more sub-pixels including a sub-pixel of the other color such as white.

The sub-pixel SP comprises a pixel circuit 1 and a display element 20 driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

At the pixel switch 2, a gate electrode is connected to a scanning line GL. Either of a source electrode and a drain electrode of the pixel switch 2 is connected to a signal line SL, and the other is connected to a gate electrode of the drive transistor 3 and the capacitor 4. At the drive transistor 3, either of the source electrode and the drain electrode is connected to a power line PL and the capacitor 4, and the other is connected to an anode of a display element 20. A cathode of the display element 20 is connected to the power supply line FL to which a common voltage is applied. The configuration of the pixel circuit 1 is not limited to the example shown in the figure.

The display element 20 is an organic light emitting diode (OLED) serving as a light emitting element. For example, the sub-pixel SP1 comprises a display element that emits light corresponding to a red wavelength, the sub-pixel SP2 comprises a display element that emits light corresponding to a green wavelength, and the sub-pixel SP3 comprises a display element that emits light corresponding to a blue wavelength. The configuration of the display element 20 will be described later.

FIG. 2 is a view showing an example of a layout of sub-pixels SP (SP1, SP2, and SP3). Four pixels PX will be focused here. In each of the pixels PX, the sub-pixels SP1, SP2, and SP3 are arranged in this order in the first direction X. In other words, a column constituted by a plurality of sub-pixels SP1 arranged in the second direction Y, a column constituted by a plurality of sub-pixels SP2 arranged in the second direction Y, and a column constituted by a plurality of sub-pixels SP3 arranged in the second direction Y are alternately arranged in the first direction X, in the display area DA.

A rib 14 is arranged at boundaries of the sub-pixels SP1, SP2, and SP3. In the example of FIG. 2, the rib 14 has a grating shape having parts located between the sub-pixels SP adjacent to each other in the first direction X and parts located between the sub-pixels SP adjacent to each other in the second direction Y. The rib 14 forms apertures OP at the sub-pixels SP1, SP2, and SP3, respectively.

The rib 14 includes a plurality of partitions PT. In the example of FIG. 2, the plurality of partitions PT include a plurality of partitions PT1 parallel to the second direction Y and a plurality of partitions PT2 parallel to the first direction X.

The partitions PT1 are located between the sub-pixels SP1 and SP2 adjacent to each other in the first direction X, between the sub-pixels SP2 and SP3 adjacent to each other in the first direction X, and between the sub-pixels SP1 and SP3 adjacent to each other in the first direction X, respectively. In other words, the partitions PT1 are located at boundaries of the sub-pixels SP of different colors.

The partitions PT2 are located between two sub-pixels SP1 adjacent to each other in the second direction Y, two sub-pixels SP2 adjacent to each other in the second direction Y, and two sub-pixels SP3 adjacent to each other in the second direction Y, respectively. In other words, the partitions PT2 are located at boundaries of the sub-pixels SP of the same color.

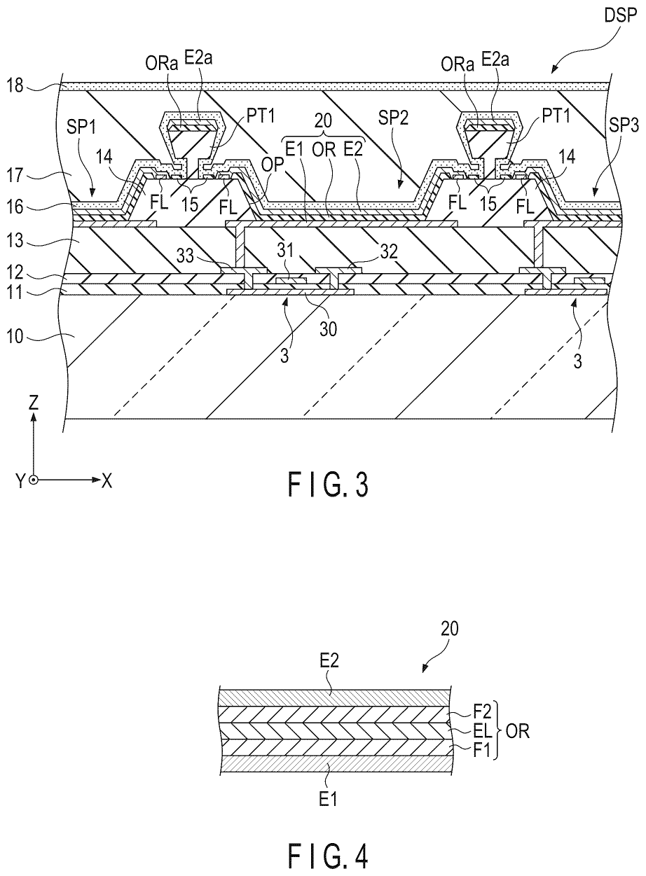

FIG. 3 is a schematic cross-sectional view showing the display device DSP along line III-III in FIG. 2. In FIG. 3, the cross-sectional structure of the sub-pixel SP2 is mainly shown, but the sub-pixels SP1 and SP3 also have the same cross-sectional structure. The drive transistor 3 and the display element 20 are shown as the elements arranged in the sub-pixel SP2, and illustration of the other elements is omitted.

The display device DSP comprises insulating layers 11, 12, and 13, a first inorganic layer 15, a second inorganic layer 16, a resin layer 17, and a third inorganic layer 18 in addition to the above-described substrate 10, rib 14, partitions PT1, and power supply lines FL.

The insulating layers 11, 12, and 13 are stacked on the substrate 10 in the third direction Z. The insulating layers 11 and 12 are formed of, for example, an inorganic material. For example, the insulating layer 13 is formed of an organic material.

The drive transistor 3 comprises a semiconductor layer 30 and electrodes 31, 32, and 33. The electrode 31 corresponds to the gate electrode. Either of the electrodes 32 and 33 corresponds to the source electrode, and the other corresponds to the drain electrode. The semiconductor layer 30 is arranged between the substrate 10 and the insulating layer 11. The electrode 31 is arranged between the insulating layers 11 and 12. The electrodes 32 and 33 are arranged between the insulating layers 12 and 13, and are in contact with the semiconductor layer 30 through a contact hole which penetrates the insulating layers 11 and 12.

The display element 20 comprises a first electrode E1, an organic layer OR, and a second electrode E2. The first electrode E1 is an electrode arranged in each sub-pixel SP, and is referred to as a pixel electrode, a lower electrode or an anode in some cases. The second electrode E2 is an electrode arranged commonly for the plurality of sub-pixels SP, and is referred to as a common electrode, an upper electrode or a cathode in some cases.

The rib 14 is arranged on the insulating layer 13. The rib 14 can be formed of an organic material. The first electrode E1 is arranged on the insulating layer 13 and overlaps with the aperture OP. A peripheral portion of the first electrode E1 is covered with the rib 14. The first electrode E1 is electrically connected to the electrode 33 through a contact hole which penetrates the insulating layer 13. The first electrode E1 is formed of a metal material. However, the first electrode E1 may be formed of a transparent conductive material such as an indium tin oxide (ITO) or an indium zinc oxide (IZO) or may be a stacked layer body of a transparent conductive material and a metal material.

The organic layer OR covers the first electrode E1 and the rib 14. The organic layer OR is in contact with the first electrode E1 through the aperture OP. A part of the organic layer OR is located on the rib 14.

The second electrode E2 covers the organic layer OR. The second electrode E2 is formed of a metal material. However, the second electrode E2 may be formed of a transparent conductive material such as ITO or IZO.

The partitions PT1 are arranged on the rib 14. The partitions PT2 shown in FIG. 2 are also arranged on the rib 14. The partitions PT1 and PT2 are formed of, for example, an organic material. The power supply line FL and the first inorganic layer 15 are arranged on the rib 14. The power supply line FL is formed of, for example, a metal material.

The second inorganic layer 16 covers the second electrode E2, the rib 14, the first inorganic layer 15, and the partitions PT1. The resin layer 17 covers the second inorganic layer 16. The resin layer 17 is formed to be thicker than, for example, the insulating layers 11, 12, and 13, the rib 14, the second inorganic layer 16, the third inorganic layer 18, and the partitions PT1. The third inorganic layer 18 covers the resin layer 17.

The first inorganic layer 15, the second inorganic layer 16, and the third inorganic layer 18 are formed of, for example, an inorganic material such as silicon oxide (SiOx) or silicon nitride (SiNx). The first inorganic layer 15 and the second inorganic layer 16 are desirably formed of the same inorganic material. Adherence of the first inorganic layer 15 and the second inorganic layer 16 is thereby improved. When the first inorganic layer 15, the second inorganic layer 16, and the third inorganic layer 18 are formed of the same inorganic material, the inorganic layers 15, 16, and 18 may be different in film density and composition ratio. In addition, for example, both the first inorganic layer 15 and the second inorganic layer 16 may be formed of a silicon-based inorganic material, similarly to a case where either of the first inorganic layer 15 and the second inorganic layer 16 is of silicon oxide and the other is of silicon nitride. Furthermore, the first inorganic layer 15 and the second inorganic layer 16 may be formed of an inorganic material of the same kind other than the silicon-based material. Even in these cases, adherence of the first inorganic layer 15 and the second inorganic layer 16 can be improved.

The second inorganic layer 16, the resin layer 17, and the third inorganic layer 18 function as sealing layers that protect the organic layer OR from moisture, and the like. Furthermore, the second inorganic layer 16, the resin layer 17, and the third inorganic layer 18 also function as planarization layers sealing layers that planarize unevenness generated by the rib 14.

FIG. 4 is a cross-sectional view showing an example of the layer configuration applicable to the organic layer OR. For example, the organic layer OR includes a first functional layer F1, a light emitting layer EL, and a second functional layer F2 which are sequentially stacked from the first electrode E1 toward the second electrode E2.

When the electric potential of the first electrode E1 is relatively higher than the electric potential of the second electrode E2, the first electrode E1 corresponds to an anode, and the second electrode E2 corresponds to a cathode. In addition, when the electric potential of the second electrode E2 is relatively higher than the electric potential of the first electrode E1, the second electrode E2 corresponds to an anode, and the first electrode E1 corresponds to a cathode.

As an example, when the first electrode E1 corresponds to an anode, the first functional layer F1 includes at least one of a hole injection layer, a hole transport layer, and an electron blocking layer, and the second functional layer F2 includes at least one of an electron transport layer, an electron injection layer, and a hole blocking layer.

When a potential difference is formed between the first electrode E1 and the second electrode E2, the light emitting layer EL emits light. In the present embodiment, it is assumed that the light emitting layers EL included in the organic layers OR of the sub-pixels SP1, SP2, and SP3 emit light of the same color (for example, white color). In this case, for example, a color filter corresponding to the color of the sub-pixels SP1, SP2, and SP3 may be arranged above the resin layer 17. In addition, a layer including quantum dots which are excited by the light emitted from the light emitting layer EL to generate light of the color corresponding to the sub-pixels SP1, SP2, and SP3 may be arranged in the sub-pixels SP1, SP2, and SP3.

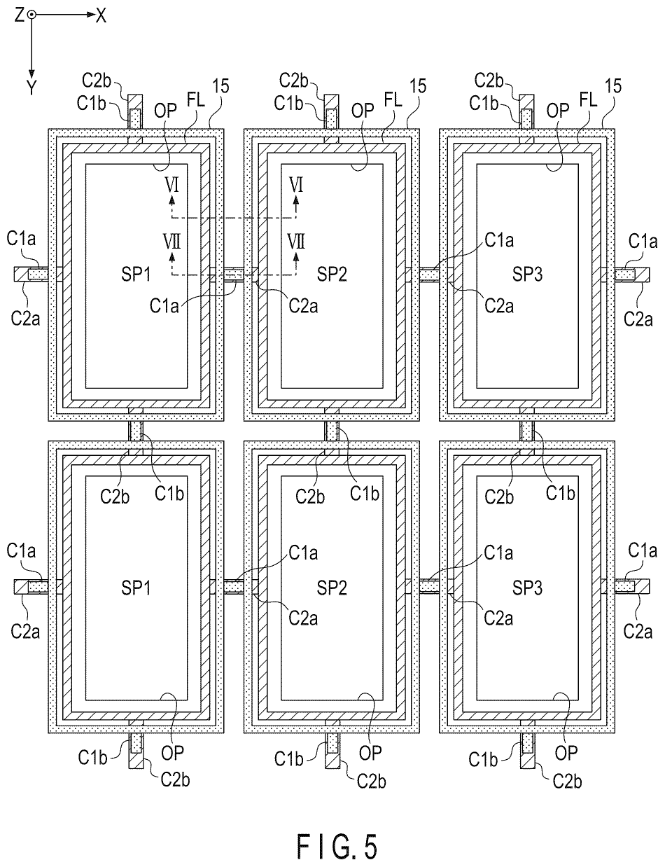

FIG. 5 is a schematic plan view showing an example of a configuration applicable to the apertures OP, the first inorganic layers 15, and the power supply lines FL. The figure shows a configuration corresponding to the sub-pixels SP1, SP2, and SP3 arranged in the first direction X and to the other sub-pixels SP1, SP2, and SP3 arranged with the sub-pixels SP1, SP2, and SP3 in the second direction Y.

In the example of FIG. 5, the first inorganic layers 15 and the power supply lines FL have a rectangular shape surrounding the aperture OP. In each of the sub-pixels SP1, SP2, and SP3, the power supply line FL is located between the aperture OP and the first inorganic layer 15.

Two first inorganic layers 15 arranged in the first direction X are connected to each other by a connection portion C1a. Two first inorganic layers 15 arranged in the second direction Y are connected to each other by a connection portion C1b. In the example of FIG. 5, the connection portion C1a connects centers of two first inorganic layers 15 in the second direction Y to each other, and the connection portion C1b connects centers of two first inorganic layers 15 in the first direction X to each other. However, the positions of the connection portions C1a and C1b are not limited to this example. In addition, two first inorganic layers 15 arranged in the first direction X may be connected to each other by a plurality of connection portions C1a. Similarly, two first inorganic layers 15 arranged in the second direction Y may be connected to each other by a plurality of connection portions C1b.

Two power supply lines FL arranged in the first direction X are connected to each other by a connection portion C2a. Two power supply lines FL arranged in the second direction Y are connected to each other by a connection portion C2b. In the example of FIG. 5, the connection portion C2a overlaps with the connection portion C1a, and the connection portion C2b overlaps with the connection portion C1b. However, each of the connection portions C2a and C2b may be provided at a position which does not overlap with the connection portions C1a and C1b. Two power supply lines FL arranged in the first direction X may be connected to each other by a plurality of connection portions C2a, and two power supply lines FL arranged in the second direction Y may be connected to each other by a plurality of connection portions C2b. In a case where the connection portion C1a and the connection portion C2a overlap, it is desirable that a width of the connection portion C1a in the second direction Y is larger than a width of the connection portion C2a in the second direction Y and that the connection portion C1a entirely covers the connection portion C2a. Similarly, in a case where the connection portion C1b and the connection portion C2b overlap, it is desirable that a width of the connection portion C1b in the second direction Y is larger than a width of the connection portion C2b in the second direction Y and that the connection portion C1b entirely covers the connection portion C2b.

Parts of the plurality of power supply lines FL connected by the connection portions C2a and C2b extend to the surrounding area SA and are connected to a wire to which the common voltage is applied. In the other example, at least one of the plurality of power supply lines FL may be connected with the wire to which the common voltage is applied, in the display area DA. In this case, the wire may be arranged in any layer between the substrate 10 and the insulating layer 13, and at least the power supply lines FL and the wire may be connected through contact holes which penetrate the rib 14 and the insulating layer 13.

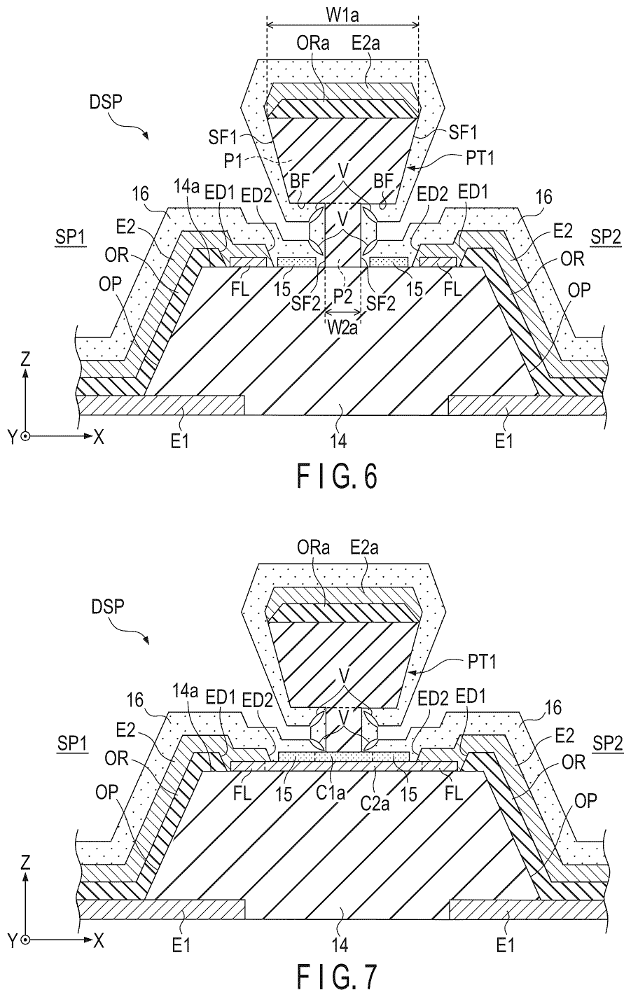

FIG. 6 is a schematic cross-sectional view showing the display device DSP along line VI-VI in FIG. 5. The substrate 10, the insulating layers 11, 12, and 13, the resin layer 17, and the third inorganic layer 18 are omitted.

The partition PT1 includes a first portion P1 and a second portion P2. The second portion is located between the first portion P1 and the rib 14 in the third direction Z. In the example of FIG. 6, the second portion P2 is in contact with the upper surface 14a of the rib 14.

The first portion P1 has a first width W1a. The second portion P2 has a second width W2a. The second width W2a is smaller than the first width W1 (W1a>W2a).

In the example of FIG. 6, a pair of side surfaces SF1 of the first portion P1 are inclined such that a distance between these side surfaces SF1 decreases from an upper end to a lower end of the first portion P1. In other words, the width of the first portion P1 is not constant in the third direction Z. The first width W1a corresponds to a maximum width of the first portion P1, and is a width of the upper end of the first portion P1 in the example shown in the figure. The pair of side surfaces SF1 may be parallel to the third direction Z. Alternatively, the pair of side surfaces SF1 may be inclined such that the distance between these side surfaces SF1 increases from the upper end to the lower end of the first portion P1. In the example of FIG. 6, a pair of side surfaces SF2 of the second portion P2 are parallel to the third direction Z. However, the pair of side surfaces SF2 may be inclined to the third direction Z.

The first portion P1 has a pair of lower surfaces BF that connect the side surfaces SF1 with the side surfaces SF2. These lower surfaces BF are opposed to the upper surface 14a of the rib 14. A shape of the partition PT1 including the first portion P1 and the second portion P2 of such a shape may be referred to as, for example, an overhang shape.

An organic layer ORa and a conductive layer E2a covering the organic layer ORa are arranged on the partition PTa (first portion P1). The organic layer ORa is formed of the same material as the organic layer OR. The conductive layer E2a is formed of the same material as the second electrode E2. The organic layer ORa is separated from the organic layers OR arranged in the sub-pixels SP1 and SP2. The conductive layer E2a is separated from the second electrodes E2 arranged in the sub-pixels SP1 and SP2.

The organic layers OR and the second electrodes E2 are formed on an entire surface of the display area DA by, for example, vacuum deposition. At this time, the organic layer ORa and the conductive layer E2a are formed by attaching materials from a deposition source to the upper surface of the partition PT1. In contrast, the materials from the deposition source can hardly be attached to the side surfaces SF1 and SF2. As a result, the organic layers OR and the organic layer ORa are separated from each other, and the second electrodes E2 and the conductive layer E2a are separated from each other.

The organic layer OR includes a first end portion ED1 on the upper surface 14a of the rib 14. The second electrode E2 includes a second end portion ED2 on the upper surface 14a. Each of the first end portion ED1 and the second end portion ED2 is separated from the second portion P2. The second end portion ED2 is located between the first end portion ED1 and the second portion P2 in the first direction X. The first end portion ED1 is covered with the second electrode E2.

The first inorganic layer 15 is located between the first end portion ED1 and the second portion P2 on the upper surface 14a. The first inorganic layer 15 is in contact with the upper surface 14a. The second portion P2 is located between the first inorganic layer 15 of the sub-pixel SP1 and the first inorganic layer 15 of the sub-pixel SP2, and separated from these first inorganic layers 15.

The power supply line FL is located between the first end portion ED1 and the first inorganic layer on the upper surface 14a. The second end portion ED2 is located between the first end portion ED1 and the first inorganic layer 15. The second electrodes E2 are in contact with the power supply lines FL. In the example of FIG. 6, the entire power supply lines FL are covered with the second electrodes E2, and the second end portions ED2 are located between the power supply lines FL and the first inorganic layers 15. However, parts of the power supply lines FL may not be covered with the second electrodes E2.

The second inorganic layers 16 are formed by a method such as chemical vapor deposition (CVD) with high film forming property on wall portions such as the side surfaces SF1 and SF2 after the second electrodes E2 are formed. In the example of FIG. 6, the second inorganic layers 16 cover the second electrodes E2, the first inorganic layers 15, and the partition PT1. More specifically, the second inorganic layers 16 cover the side surfaces SF1, the side surfaces SF2, and the conductive layer E2a. The second inorganic layers 16 may not cover parts of the side surfaces SF1 and SF2.

FIG. 7 is a schematic cross-sectional view showing the display device DSP along line VII-VII in FIG. 5. The connection portions C1a and C2a are included in this cross section. The connection portion C1a and the first inorganic layer 15 are integrally formed of the same material. The connection portion C2a and the power supply lines FL are integrally formed of the same material.

The connection portion C2a is arranged on the upper surface 14a of the rib 14. The connection portion C1a is arranged on the connection portion C2a. At the position of this cross section, the first inorganic layer 15 is also arranged on the connection portion C2a, and the second portion P2 of the partition PT1 is further arranged on the connection portion C1a.

In FIG. 6 and FIG. 7, the structure near the boundary between the sub-pixels SP1 and SP2 is shown, but the same structure can also be applied to the vicinity of the boundary between the sub-pixels SP2 and SP3 and the vicinity of the boundary between the sub-pixels SP1 and SP3. The same shape as that of the partition PT1 can be applied to the partitions PT2 shown in FIG. 2. The structures shown in FIG. 6 and FIG. 7 can also be applied to the cross-sectional structures near the boundary between two sub-pixels SP1 arranged in the second direction Y, the boundary between two sub-pixels SP2 arranged in the second direction Y, and the boundary between two sub-pixels SP3 arranged in the second direction Y.

When the second inorganic layer 16 is formed by the vapor deposition, the inorganic layer grows from one surface and the inorganic layer also grows from the other surface, in the vicinity of a corner composed of two surfaces that form a large angle. When these inorganic layers approach each other, the inflow of gas into a part between them may be suppressed and crevasse-like voids (gaps) may be formed. Since the resin layer 17 (see FIG. 3) also hardly enters the voids, the air may remain in the voids. In the example of FIG. 6 and FIG. 7, voids V

are formed near the base of the second portion P2. In addition, voids V are also formed near the corners of the side surfaces SF2 and the lower surfaces BF. In general, the organic layers OR have a low resistance to moisture and, when the moisture contained in the air of the voids V reaches the organic layers OR through interfaces between the rib 14 and the second electrodes E2 or the like, this may cause the display failure such as a decrease in luminance of the display elements 20 (generation of dark spots).

In contrast, in the present embodiment, the first inorganic layers 15 are arranged between the first end portions ED1 of the organic layers OR and the partitions PT1, and the first inorganic layers 15 are in contact with the upper surfaces 14a and the second inorganic layers 16. Since the adherence between the first inorganic layers 15 and the second inorganic layers 16 formed of an inorganic material is desirable, moisture reaching from the voids V to the organic layers OR can be suppressed. The display quality of the display device DSP can be thereby improved.

The advantage achieved by the present embodiment has been described based on the cross section including the partitions PT1 as shown in FIG. 6 and FIG. 7, but the same advantages can be obtained in the vicinity of the partitions PT2, too.

Second to sixth embodiments of the display device DSP will be described below. The same configuration as that of the preceding embodiment can be applied for the configuration not specifically mentioned in each of the embodiments.

### Second Embodiment

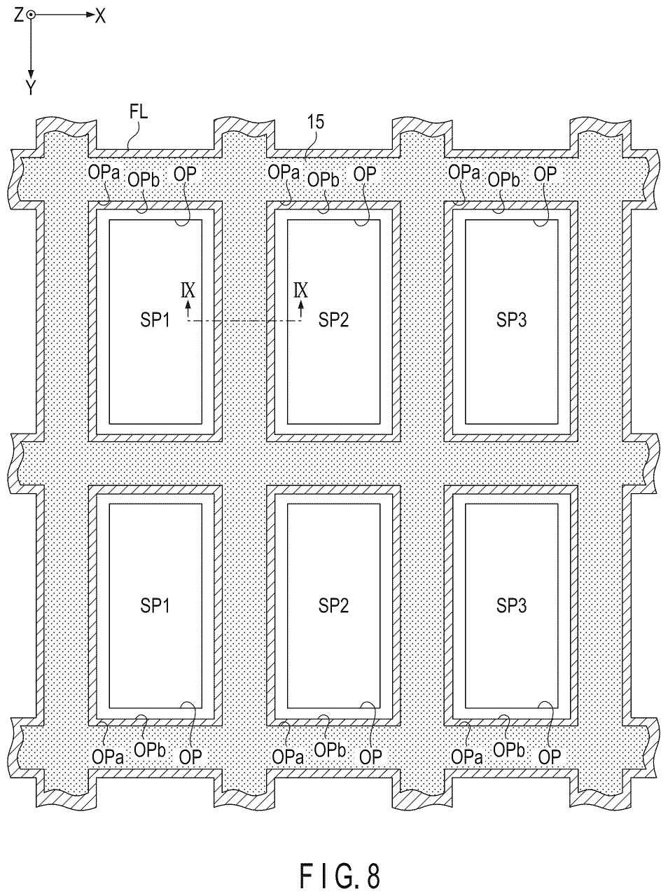

FIG. 8 is a schematic plan view showing a first inorganic layer 15 and a power supply line FL in a display device DSP according to a second embodiment. In the present embodiment, the first inorganic layer 15 and the power supply line FL have a grating shape having parts located between sub-pixels SP (SP1, SP2, and SP3) adjacent to each other in the first direction X and parts located between the sub-pixels SP adjacent to each other in the second direction Y. The first inorganic layer 15 forms apertures OP at the sub-pixels SP1, SP2, and SP3, respectively. The power supply line FL forms apertures OP at the sub-pixels SP1, SP2, and SP3, respectively.

The apertures OP are located inside apertures OPb. The apertures OPb are located inside apertures OPa. In other words, a width of the power supply line FL in the first direction X is larger than a width of the first inorganic layer 15 in the first direction X. In addition, a width of the power supply line FL in the second direction Y is larger than a width of the first inorganic layer 15 in the second direction Y.

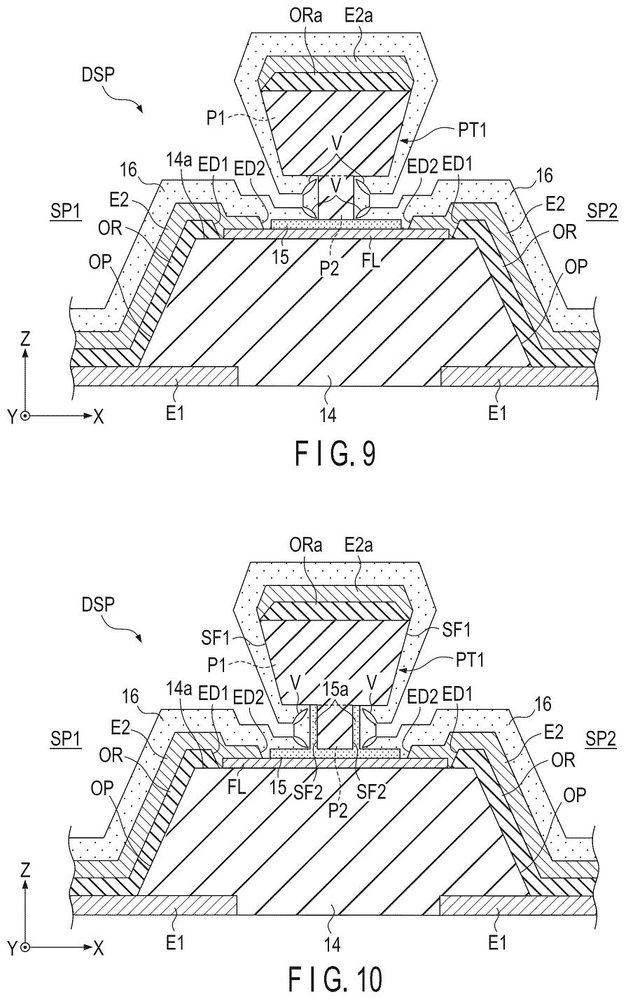

FIG. 9 is a schematic cross-sectional view showing the display device DSP along line IX-IX in FIG. 8. The power supply line FL is arranged on an upper surface 14a of a rib 14. The first inorganic layer 15 is arranged on the power supply line FL. A second portion P2 of a partition PT1 is arranged on the first inorganic layer 15.

The first inorganic layer 15 is located between a second end portion ED2 of a second electrode E2 of a sub-pixel SP1 and a second end portion ED2 of a second electrode E2 of a sub-pixel SP2, in the first direction X. The power supply line FL is located between a first end portion ED1 of the organic layer OR of the sub-pixel SP1 and a first end portion ED1 of the organic layer OR of the sub-pixel SP2, in the first direction X.

The first inorganic layer 15 covers a part of the power supply line FL. Both end portions of the power supply line FL in the first direction X are exposed from the first inorganic layer 15. In each of the sub-pixels SP1 and SP2, the second electrode E2 is in contact with the portion of the power supply line FL, which is exposed from the first inorganic layer 15. In each of the sub-pixels SP1 and SP2, the first inorganic layer 15 is in contact with a second inorganic layer 16.

According to a configuration of the present embodiment, since the first inorganic layer 15 is arranged at an entire surrounding of the second portion P2 of the partition PT1, a contact area between the first inorganic layer 15 and the second inorganic layer 16 can be increased. The moisture reaching from voids V to the organic layer OR can be thereby effectively suppressed.

The structure near the boundary between the sub-pixels SP1 and SP2 is shown in FIG. 9, but the same structure can be applied to the vicinity of the boundary between the sub-pixels SP2 and SP3 and the vicinity of the boundary between the sub-pixels SP1 and SP3. The structure shown in FIG. 9 can also be applied to the cross-sectional structures near the boundary between two sub-pixels SP1 arranged in the second direction Y, the boundary between two sub-pixels SP2 arranged in the second direction Y, and the boundary between two sub-pixels SP3 arranged in the second direction Y.

### Third Embodiment

FIG. 10 is a schematic cross-sectional view showing a display device DSP according to a third embodiment. A cross-sectional structure shown in this figure is different from the example of FIG. 9 in that a first inorganic layer 15 includes portions 15a which cover a pair of side surfaces SF2 of a partition PT1. A second inorganic layer 16 covers these portions 15a. In other words, the portions 15a are located between the side surfaces SF2 and the second inorganic layer 16.

In the example of FIG. 10, the portions 15a cover the entire side surfaces SF2. For example, the portions 15a may cover lower areas of the side surfaces SF2 but may not cover upper areas of the side surfaces SF2. The portions 15a may further cover at least parts of the side surfaces SF1. In addition, the portions 15a may cover the entire partition PT1.

When the first inorganic layer 15 covers at least a part of the side surfaces of the partition PT1, similarly to the present embodiment, the first inorganic layer 15 and the second inorganic layer 16 can be made to be in contact with each other in a wider range. The moisture reaching from voids V to the organic layer OR can be thereby suppressed more effectively.

The structure near the boundary between the sub-pixels SP1 and SP2 is shown in FIG. 10, but the same structure can be applied to the vicinity of the boundary between the sub-pixels SP2 and SP3 and the vicinity of the boundary between the sub-pixels SP1 and SP3. The structure shown in FIG. 10 can also be applied to the cross-sectional structures near the boundary between two sub-pixels SP1 arranged in the second direction Y, the boundary between two sub-pixels SP2 arranged in the second direction Y, and the boundary between two sub-pixels SP3 arranged in the second direction Y.

### Fourth Embodiment

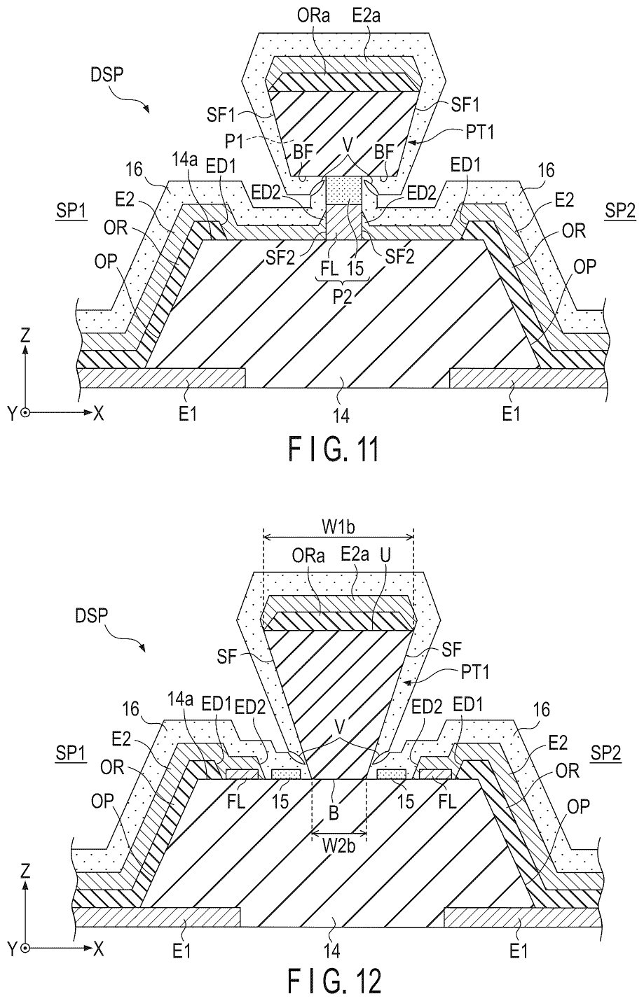

FIG. 11 is a schematic cross-sectional view showing a display device DSP according to a fourth embodiment. In the example of this figure, a second portion P2 of a partition PT1 includes a power supply line FL and a first inorganic layer 15. The power supply line FL is arranged on an upper surface 14a of a rib 14. The first inorganic layer 15 is arranged on the power supply line FL. Furthermore, a first portion P1 is arranged on the first inorganic layer 15.

For example, a thickness of the power supply line FL is larger than a thickness of a second electrode E2. The power supply line FL may be entirely formed of a metal material or may have a structure in which a surface of an insulating layer is covered with a metal material. In the example of FIG. 11, the thickness of the power supply line FL is the same as the thickness of the first inorganic layer 15. In another example, the thickness of the power supply line FL may be different from the thickness of the first inorganic layer 15. For example, if the thickness of the power supply line FL is larger than the thickness of the first inorganic layer 15, connection between the power supply line FL and the second electrode E2 can be facilitated.

Second end portions ED2 of the second electrodes E2 are in contact with side surfaces of the power supply line FL (i.e., lower areas of the side surfaces SF2). In the example of FIG. 11, the second end portions ED2 are not in contact with side surfaces of the first inorganic layer 15. A second inorganic layer 16 is in contact with the side surfaces of the first inorganic layer 15 (i.e., lower areas of the side surfaces SF2).

In the example of FIG. 11, voids V are formed near corners of the side surfaces SF2 and the lower surfaces BF. Since the first inorganic layer 15 and the second inorganic layer 16 are in contact with each other between the voids V and the organic layer OR, path of moisture from the voids V to the organic layer OR can be interrupted. Therefore, moisture reaching from voids V to the organic layer OR can be effectively suppressed similarly to each of the above-described embodiments.

The structure near the boundary between the sub-pixels SP1 and SP2 is shown in FIG. 11, but the same structure can be applied to the vicinity of the boundary between the sub-pixels SP2 and SP3 and the vicinity of the boundary between the sub-pixels SP1 and SP3. The same shape as that of the partition PT1 can be applied to the partitions PT2. The structure shown in FIG. 11 can also be applied to the cross-sectional structures near the boundary between two sub-pixels SP1 arranged in the second direction Y, the boundary between two sub-pixels SP2 arranged in the second direction Y, and the boundary between two sub-pixels SP3 arranged in the second direction Y.

### Fifth Embodiment

FIG. 12 is a schematic cross-sectional view showing a display device DSP according to a fifth embodiment. The cross-sectional structure in this figure is different from the example of FIG. 6 in shape of a partition PT1. The partition PT1 shown in FIG. 12 includes an upper portion U and a lower portion B. The upper portion U corresponds to a portion which is the widest of the partition PT1, and is an upper end (upper surface) of the partition PT1 in the example of FIG. 12. The lower portion B corresponds to a portion which is the narrowest of the partition PT1, and is a lower end (lower surface) of the partition PT1 in the example of FIG. 12.

The upper portion U has a first width W1b. The lower portion B has a second width W2b smaller than the first width W1b (W1b>W2b). A pair of side surfaces SF of the partition PT1 are inclined such that a distance between these side surfaces SF decreases from the upper portion U to the lower portion B. This shape of the partition PT1 may be referred to as an inverse tapered shape.

Even if the partition PT1 has such a shape, the organic layers OR and the second electrodes E2 can be separated between the sub-pixels SP1 and SP2. An organic layer ORa and a conductive layer E2a are formed on the upper portion U, similarly to the example of FIG. 6.

The shapes and positions of the first inorganic layers 15, the power supply lines FL, the second electrodes E2, and the organic layers OR are the same as those in the example of FIG. 6. Second inorganic layers 16 cover the second electrodes E2 and the first inorganic layers 15, and also cover side surfaces SF and conductive layers E2a.

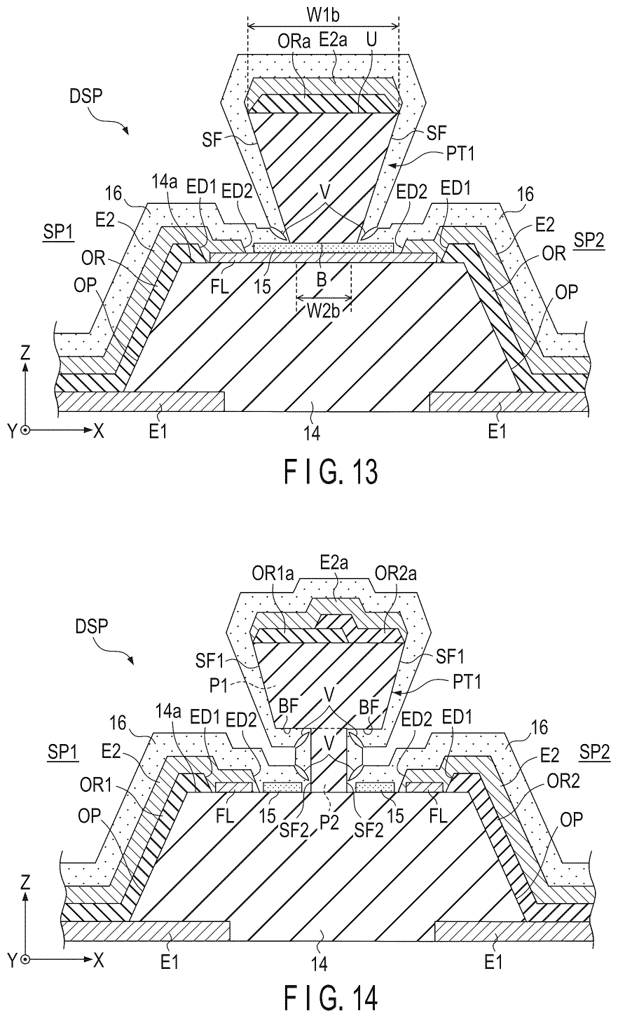

FIG. 13 is a schematic cross-sectional view showing another example of the display device DSP according to the fifth embodiment. Similarly to the example of FIG. 9, a power supply line FL having a large width is arranged on an upper surface 14a of a rib 14, the first inorganic layer 15 is arranged on the power supply line FL, and the partition PT1 is arranged on the first inorganic layer 15.

In each of the sub-pixels SP1 and SP2, the second electrode E2 is in contact with the portion of the power supply line FL, which is exposed from the first inorganic layer 15. In each of the sub-pixels SP1 and SP2, the first inorganic layer 15 is in contact with a second inorganic layer 16. A shape of the partition PT1 is the same as that in the example of FIG. 12. In the example of FIG. 13, the first inorganic layer 15 may cover at least parts of side surfaces SF.

Voids V can be formed near a base of the partition PT1, in the structures of FIG. 12 and FIG. 13, too. Even in this case, since the first inorganic layer 15 and the second inorganic layer 16 are in close contact with each other, moisture reaching from the voids V to the organic layers OR can be suppressed.

In FIG. 12 and FIG. 13, the structures near the boundary between the sub-pixels SP1 and SP2 are shown, but the same structures can also be applied to the vicinity of the boundary between the sub-pixels SP2 and SP3 and the vicinity of the boundary between the sub-pixels SP1 and SP3. The same shape as that of the partition PT1 can be applied to the partitions PT2. The structures shown in FIG. 12 and FIG. 13 can also be applied to the cross-sectional structures near the boundary between two sub-pixels SP1 arranged in the second direction Y, the boundary between two sub-pixels SP2 arranged in the second direction Y, and the boundary between two sub-pixels SP3 arranged in the second direction Y.

### Sixth Embodiment

It is assumed in each of the above-described first to fifth embodiments that all the light emitting layers EL included in the organic layers OR of the sub-pixels SP1, SP2, and SP3 emit light of the same color. In the present embodiment, it is assumed that the light emitting layers EL included in the organic layers OR of the sub-pixels SP1, SP2, and SP3 emit light of different colors.

FIG. 14 is a schematic cross-sectional view showing a display device DSP according to a sixth embodiment. The structure of the boundary between the sub-pixels SP1 and SP2 is shown in this figure, but the same structure can also be applied to the boundary between the sub-pixels SP2 and SP3 and the boundary between the sub-pixels SP1 and SP3. A shape of a partition PT1 shown in FIG. 14 is the same as that in the example of FIG. 6.

In the example of FIG. 14, an organic layer OR1 is arranged in the sub-pixel SP1, and an organic layer OR2 is arranged in the sub-pixel SP2. The organic layer OR1 comprises, for example, the light emitting layer EL which emits red light. The organic layer OR2 comprises, for example, the light emitting layer EL which emits green light. Although not shown in the cross section of FIG. 14, the organic layer OR arranged in the sub-pixel SP3 comprises the light emitting layer EL which emits blue light.

The organic layer OR1 covers a first electrode E1 of the sub-pixel SP1 through an aperture OP, and covers a part of an area of a rib 14 which is closer to the sub-pixel SP1 side than the partition PT1. The organic layer OR2 covers a first electrode E1 of the sub-pixel SP2 through an aperture OP, and covers a part of an area of the rib 14 which is closer to the sub-pixel SP2 side than the partition PT1.

Organic layers OR1a and OR2a, and a conductive layer E2a covering the organic layers OR1a and OR2a are arranged on the partition PT1. The organic layer OR1a is formed of the same material as the organic layer OR1. The organic layer OR2a is formed of the same material as the organic layer OR2. The conductive layer E2a is formed of the same material as the second electrode E2. The organic layer OR1a is separated from the organic layer OR1. The organic layer OR2a is separated from the organic layer OR2. In the example of FIG. 14, a part of the organic layer OR1a is covered with the organic layer OR2a.

The organic layer OR1 is formed by vacuum deposition using a mask which opens in a shape of the sub-pixel SP1. At this time, by attaching materials from a deposition source to the upper surface of the partition PT1, the organic layer OR1a is formed. The organic layer OR2 is formed by vacuum deposition using a mask which opens in a shape of the sub-pixel SP2, after the formation of the organic layer OR1. At this time, by attaching materials from a deposition source to the upper surface of the partition PT1, the organic layer OR2a is formed.

The configuration of the present embodiment can also be applied to any one of the above-described embodiments.

In each of the above-described embodiments, at least a part of the first inorganic layer 15 is located between the first end portion ED1 and the partition PT1 (or the partition PT2) and is in contact with the second inorganic layer 16. The common advantage of suppressing moisture reaching from voids V to the organic layer OR can be thereby obtained.

In each embodiment, the partition PT1 may be formed of an inorganic material. In this case, adherence between the second inorganic layer 16 and the partition PT1 is improved, and moisture reaching the organic layers OR can be suppressed more effectively.

In the example of FIG. 2, the partitions PT1 and the partitions PT2 are arranged at the boundaries of the sub-pixels SP1, SP2, and SP3. As a result, the organic layers OR arranged in the respective sub-pixels SP1, SP2, and SP3, and the second electrodes E2 arranged in the respective sub-pixels SP1, SP2, and SP3 are separated, and crosstalk between the adjacent sub-pixels SP can be suppressed.

Since an influence given to the display quality by the crosstalk between the sub-pixels SP of the same color is small, the partitions PT2 may not be arranged. In this case, the organic layers OR of the sub-pixels SP of the same color arranged in the second direction Y are connected. Similarly, the second electrodes E2 of the sub-pixels SP of the same color arranged in the second direction Y are connected.

All of the display devices that can be implemented by a person of ordinary skill in the art through arbitrary design changes to the display devices described above as embodiments of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A display device comprising:
a rib including an aperture and an upper surface;
a partition arranged on the upper surface of the rib;
a first electrode overlapping with the aperture;
an organic layer including a first end portion located on the upper surface, and covering the first electrode;
a second electrode including a second end portion located on the upper surface, and covering the organic layer;
a first inorganic layer arranged on the rib; and
a second inorganic layer covering the partition, the second electrode, and the first inorganic layer,
wherein at least a part of the first inorganic layer is located between the first end portion and the partition and is in contact with the second inorganic layer.

2. The display device of claim 1, wherein
the second end portion is located between the first end portion and the first inorganic layer.

3. The display device of claim 1, wherein
the partition is in contact with the upper surface of the rib, and
the first inorganic layer is located between the first end portion and the partition.

4. The display device of claim 3, wherein
the first inorganic layer has a frame shape surrounding the aperture in plan view.

5. The display device of claim 1, wherein
the partition is arranged on the first inorganic layer.

6. The display device of claim 1, wherein
the partition has a side surface, and
the second inorganic layer covers at least a part of the side surface.

7. The display device of claim 6, wherein
a part of the first inorganic layer is located between the side surface and the second inorganic layer.

8. The display device of claim 1, wherein
the partition includes a first portion having a first width, and a second portion having a second width smaller than the first width, and
the second portion is located between the first portion and the rib.

9. The display device of claim 1, further comprising:
a power supply line arranged on the rib, wherein
the second electrode is in contact with the power supply line.

10. The display device of claim 9, wherein
the power supply line is located between the first inorganic layer and the first end portion, on the upper surface of the rib.

11. The display device of claim 10, wherein
the power supply line has a frame shape surrounding the aperture in plan view.

12. The display device of claim 9, wherein
the first inorganic layer covers a part of the power supply line.

13. A display device comprising:
a rib including an aperture and an upper surface;
a partition arranged on an upper surface of the rib and including a first inorganic layer;
a first electrode overlapping with the aperture;
an organic layer including a first end portion located on the upper surface, and covering the first electrode;
a second electrode including a second end portion located on the upper surface, and covering the organic layer; and
a second inorganic layer covering the partition and the second electrode,
wherein
the partition includes a first portion having a first width, and a second portion having a second width smaller than the first width,
the second portion is located between the first portion and the rib and includes the first inorganic layer, and
at least a part of the first inorganic layer is in contact with the second inorganic layer.

14. The display device of claim 13, wherein
the partition has a side surface, and
the second inorganic layer covers at least a part of the side surface.

15. The display device of claim 13, wherein
the second portion further includes a power supply line, and
the second electrode is in contact with the power supply line.

16. The display device of claim 15, wherein
the first inorganic layer is arranged on the power supply line.

17. The display device of claim 15, wherein
the power supply line has a frame shape surrounding the aperture in plan view.
